(19) United States
(12) Patent Application Publication
(10) Pub. No.: US 2011/0037745 A1
(43) Pub. Date: Feb. 17, 2011

(54) LEVEL SHIFT OUTPUT CIRCUIT AND PLASMA DISPLAY APPARATUS USING THE SAME

(75) Inventor: Kazunari TAKASUGI, Kanagawa (JP)

Correspondence Address: YOUNG & THOMPSON, 209 Madison Street, Suite 500, Alexandria, VA, 22314, US

(73) Assignee: RENESAS ELECTRONICS CORPORATION, Kanagawa (JP)

(21) Appl. No.: 12/839,814

(22) Filed: Jul. 20, 2010

(30) Foreign Application Priority Data
Aug. 11, 2009 (JP) 2009-186321

(51) Int. Cl. G09G 5/00; H03L 5/00; G05F 3/02; G09G 3/28

(52) U.S. Cl. 345/211; 327/333; 327/530; 345/60

(57) ABSTRACT

A level shift output circuit includes a level shifter interconnecting first and second power supplies that supply first and second voltages, the second being lower than the first voltage. The circuit outputs complimentary first and second output signals responsive to complimentary first and second input signals. High breakdown voltage inverters interconnect the first and second power supplies, and are configured to output a third output signal responsive to a first control signal and the first output signal from the level shifter and output a fourth output signal which is complimentary with the third output signal, responsive to a second control signal complimentary with the first control signal, and the second output signal. P-type transistors interconnect the first power supply and a power supply output node, and respectively supply the first voltage to the power supply output node in response to the fourth output signals from the high breakdown voltage inverters.

### INCORPORATION BY REFERENCE

This patent application claims a priority on convention based on Japanese Patent Application No. 2009-186321 filed on Aug. 11, 2009. The disclosure thereof is incorporated herein by reference.

### TECHNICAL FIELD

The present invention relates to a level shift output circuit which performs ON/OFF control on a high breakdown voltage P-type MOSFET.

### BACKGROUND ART

In a typical level shift output circuit, a level shifter and a high breakdown voltage inverter are used to perform ON/OFF control on a high breakdown voltage P-type MOSFET.

The level shifter includes first and second P-type MOSFETs or transistors and first and second N-type transistors. The high breakdown voltage inverter includes a P-type transistor and an N-type transistor.

In the level shifter, it is assumed that the first and second P-type transistors are connected to a first power supply voltage. The first N-type transistor is connected between a gate of the second P-type transistor, the first P-type transistor and a second power supply voltage, and an input signal is supplied to a gate thereof. The second N-type transistor is connected between a gate of the first P-type transistor, the second P-type transistor and a gate of the P-type transistor of the high breakdown voltage inverter and the second power supply NGND, and the input signal is supplied to a gate thereof.

The P-type transistor of the high breakdown voltage inverter is connected between the first power supply and a gate of a third switch SW3. The N-type transistor of the high breakdown voltage inverter is connected between an input of a switch (a gate of the high breakdown voltage P-type transistor) and the second power supply. That is, an output of the high breakdown voltage inverter is connected to the input of the switch.

Depending on an application, the high breakdown voltage P-type transistor is required to have a high breakdown voltage (approximately 60 V to 100 V) and high current capacity (approximately several A to 10 A). Accordingly, provided that the sufficient current may not flow due to the restriction on an inspection apparatus in a step for test a switch characteristic, a detection rate of defects will be lowered.

As described above, a general level shift output circuit includes a level shifter, a high breakdown voltage inverter and a switch. In contrast, a level shift output circuit described in Patent Literature 1 includes two level shifters, two high breakdown voltage inverters and two switches (high breakdown voltage P-type transistors).

In a technique described in the Patent Literature 1, the level shift output circuit includes a first group including a first level shifter, a first high breakdown voltage inverter and a first switch, and a second group including a second level shifter, a second high breakdown voltage inverter and a second switch. The first and second switches share an output in common. Accordingly, each of the first and second groups is controlled independently of each other and the two high breakdown voltage P-type transistors are arranged in parallel, thereby the current capacity is distributed.

### Citation List:

[Patent Literature 1]: JP-A-Heisei 6-204847

### SUMMARY OF THE INVENTION

A high breakdown voltage transistor generally has a large element size so that a chip area is large, compared to a low breakdown voltage transistor. In the technique described in the Patent Literature 1, the chip area is increased by arranging two level shifters and two high breakdown voltage inverters. In addition, as the number of the level shifters is increased, the power consumption amount is increased.

Thus, in the technique described in the Patent Literature 1, the chip area and the power consumption amount are increased even if the current is distributed to high breakdown voltage P-type transistors.

In an aspect of the present invention, a level shift output circuit includes: a level shifter connected between a first power supply which supplies a first voltage and a second power supply which supplies a second voltage which is lower than the first voltage, and configured to output a first output signal in response to a first input signal, and output a second output signal which is complimentary with the first output signal, in response to a second input signal which is complimentary with the first input signal; a plurality of high breakdown voltage inverters connected between the first power supply and the second power supply, and configured to output a third output signal in response to a first control signal and the first output signal from the level shifter and output a fourth output signal which is complimentary with the third output signal, in response to a second control signal which is complimentary with the first control signal, and the second output signal from the level shifter; and a plurality of P-type transistors connected between the first power supply and a power supply output node, and configured to respectively supply the first voltage to the power supply output node in response to the fourth output signals from the plurality of high breakdown voltage inverters.

In another aspect of the present invention, a high breakdown voltage transistor control circuit includes: the above level shift output circuit; and an input signal processing circuit configured to execute in a first mode, a process of outputting the first input signal to the level shifter in the level shift output circuit, and of outputting the first control signal to the plurality of high breakdown voltage inverters in the level shift output circuit, and execute in a second mode, a process of outputting the second input signal to the level shifter and outputting the second control signal to the plurality of high breakdown voltage inverters.

In a still another aspect of the present invention, a power recovery circuit includes: the above level shift output circuit; a power recovery capacitance element connected between a first node and the second power supply; an inductance element connected between a second node and the power supply output node; a first diode having an anode and a cathode connected with the second node; a second diode having a cathode and an anode connected with the second node; a first switch connected between the power supply output node and the second power supply; a second switch connected between the first node and the anode of the first diode; a third switch connected between the first power supply and the power supply output node, as the plurality of high breakdown voltage P-type transistors in the level shift output circuit; a fourth switch connected between the first node and the cathode of the second diode; and an input signal processing circuit connected with the first to fourth switches and configured to turn on the first to fourth switches in this order. A voltage supplied to the power supply output node is used as a power supply voltage of a high breakdown voltage buffer, and a capacitance element is connected with an output of the high breakdown voltage buffer through a data electrode. When the first switch is turned on, electric charges are accumulated in the power recovery capacitance element. When the second switch are turned on, the electric charges accumulated in the power recovery capacitance element are supplied to the capacitance element through the second switch, the first diode, the inductance element, the power supply output node, and the high breakdown voltage buffer. When the third switch is turned on, the first voltage is supplied to the power supply output node. When the fourth switch is turned on, the electric charges accumulated in the capacitance element is accumulated by the power recovery capacitance element through the high breakdown voltage buffer, the power supply output node, the inductance element, the second diode, the fourth switch.

In a yet still another aspect of the present invention, a plasma display apparatus includes: the above power recovery circuit; a plurality of pairs of discharge electrodes of a plurality of sustain electrodes and a plurality of scan electrodes; a plurality of data electrodes provided to oppose to the plurality of pairs of discharge electrodes, and to form a plurality of display cells as a plurality of capacitance elements at intersections of the plurality of pairs of discharge electrodes and the plurality of data electrode; a scan driver configured to drive the plurality of scan electrodes; a sustain driver configured to drive the plurality of sustain electrodes; and a data driver configured to drive the plurality of data electrodes. The data driver includes: an output control circuit configured to convert a video image into data pulse voltages in an address period; a plurality of level shift circuits provided respectively for the plurality of data electrodes to convert voltage levels of the data pulse voltage into write levels in the plurality of display cells; and a plurality of high breakdown voltage buffers provided respectively for the plurality of data electrodes to output the data pulse voltages from the plurality of level shift circuits to the plurality of data electrodes. An output of the power recovery circuit is used for power for the plurality of level shift circuits and the plurality of high breakdown voltage buffers.

As described above, in the present invention, an increase of an area due to the level shifter is less compared to an increase of an area in the conventional technique.

In addition, according to the level shift output circuit of the present invention, there is no increase of the power consumed in the level shifter.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a block diagram showing a configuration of a plasma display apparatus to which a level shift output circuit according to an embodiment of the present invention is applied;

FIG. 2 is a block diagram showing a configuration of a data driver in FIG. 1;

FIG. 3 is a circuit diagram showing a configuration of a level shift circuit and a high breakdown voltage buffer in FIG. 2;

FIG. 4 shows timing charts in an operation of the plasma display apparatus;

FIG. 5 is a block diagram showing a configuration of a power recovery circuit in FIG. 1;

FIG. 6 shows timing charts in an operation of the power recovery circuit in FIG. 5;

FIG. 7 is a block diagram showing a specific example of the circuit in FIG. 5;

FIG. 8 is a circuit diagram showing a configuration of a general level shift output circuit;

FIG. 9A shows a detection rate of defects when a third switch in FIG. 8 includes a single high breakdown voltage P-type transistor;

FIG. 9B shows a detection rate of defects when the third switch in FIG. 8 includes two high breakdown voltage P-type transistors in parallel;

FIG. 10 is a block diagram showing a configuration of a level shift output circuit in the power recovery circuit according to an embodiment of the present invention;

FIG. 11A is a circuit diagram showing an operation of the level shift output circuit in the embodiment in a first mode;

FIG. 11B is a circuit diagram showing the operation of the level shift output circuit in the embodiment in a second mode;

FIGS. 11C and 11D are circuit diagrams showing the operation of the level shift output circuit according to the embodiment in a test mode;

FIG. 12 is a block diagram showing a configuration of a high breakdown voltage transistor control circuit in the power recovery circuit according to the embodiment of the present invention; and

FIG. 13 is an example when the level shift output circuit according to the embodiment of the present invention is applied to a high breakdown voltage output buffer.

### DESCRIPTION OF EMBODIMENTS

Hereinafter, a level shift output circuit according to the present invention will be described in detail with reference to the attached drawings. The level shift output circuit according to the present invention may be applied to, for example, a power recovery circuit in a plasma display apparatus.

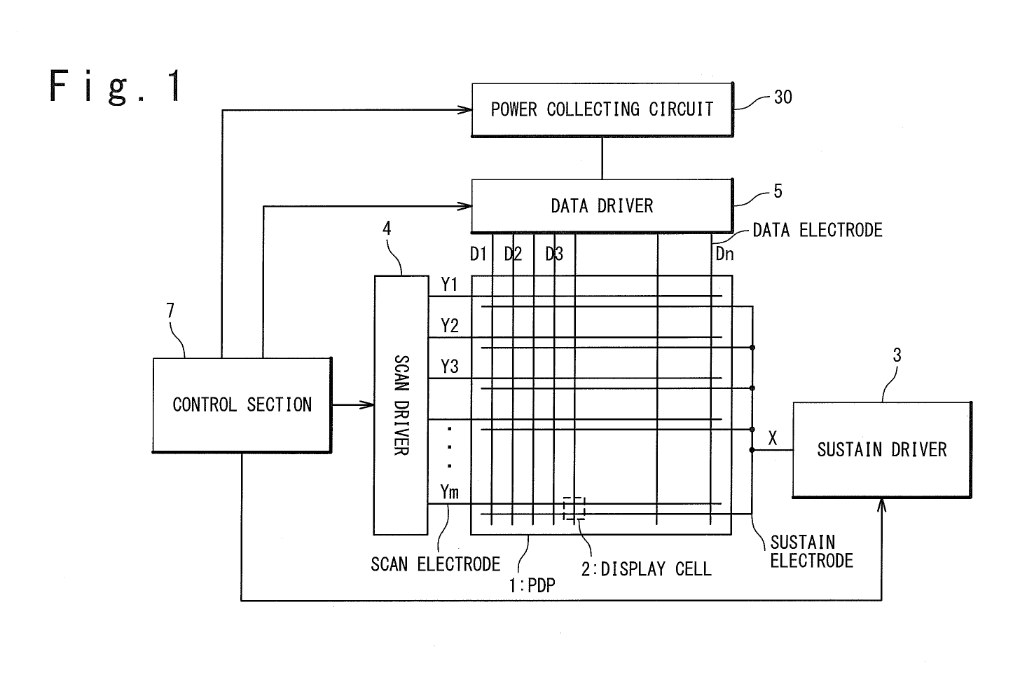

FIG. 1 illustrates a configuration of a plasma display apparatus. Referring to FIG. 1, the plasma display apparatus includes a plasma display panel (PDP) 1, a plurality of discharge electrode pairs and a plurality of data electrodes D1 to Dn (n represents an integer equal to or more than 2). The plurality of discharge electrode pairs includes a plurality of sustain electrodes X and a plurality of scan electrodes Y1 to Ym (m represents an integer equal to or more than 2). The plurality of data electrodes D1 to Dn are disposed to oppose to the plurality of discharge electrode pairs so that a display cell 2, which is a capacitor element, is formed at each of the intersections with the plurality of discharge electrode pairs and the data electrodes. Accordingly, the plasma display panel 1 includes the display cells 2 arranged in m rows and n columns.

The plasma display apparatus further includes a scan driver 4 for driving the plurality of scan electrodes Y1 to Ym, a sustain driver 3 for driving the plurality of sustain electrodes X, a data driver 5 for driving the plurality of data electrodes D1 to Dn, a control section 7 and a power recovery circuit 30.

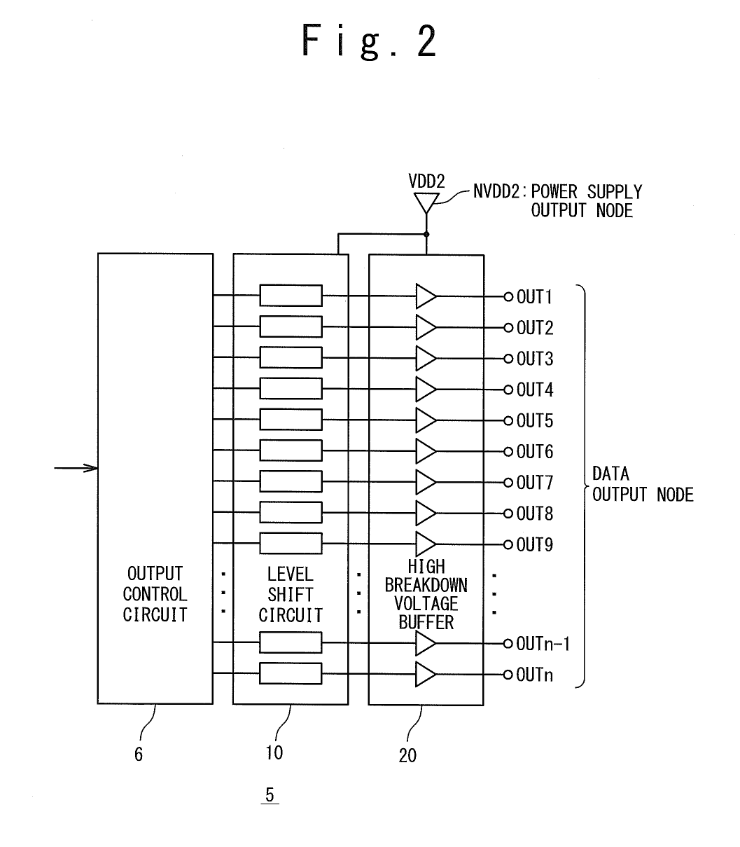

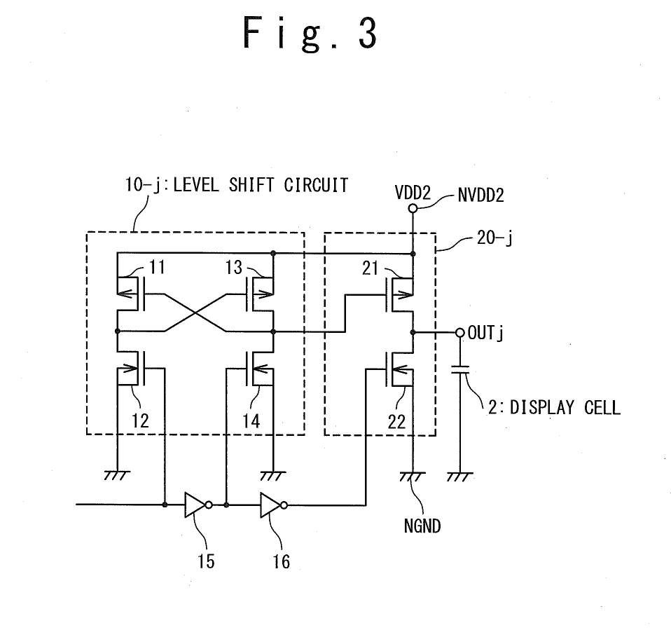

FIG. 2 illustrates a configuration of the data driver 5 in FIG. 1. Referring to FIG. 2, the data driver 5 includes an output control circuit 6, a level shift unit 10 and a high breakdown voltage buffer unit 20. The level shift unit 10 includes a plurality of level shift circuits 10-1 to 10-n, which are respectively disposed for the plurality of date electrodes D1 to Dn (see FIG. 3). The high breakdown voltage buffer unit 20 includes a plurality of high breakdown voltage buffers 20-1 to 20-n, which are disposed for the plurality of data electrodes D1 to Dn and connected to output of the plurality of level shift circuits 10-1 to 10-n, respectively (see FIG. 3). The outputs of the plurality of high breakdown voltage buffers 20-1 to 20-n are respectively connected to data output nodes OUT1 to OUTn connected to the plurality of data electrodes D1 to Dn. As described later, a power supply output node NVDD2 is connected to an output of the power recovery circuit 30. A voltage VDD2 supplied to the power supply output node NVDD2 is used as a power supply voltage for the plurality of level shift circuits 10-1 to 10-n and the plurality of high breakdown voltage buffers 20-1 to 20-n.

FIG. 3 illustrates a configuration of the level shift circuit 10-j (j represents an integer which satisfies 1·j·n) and the high breakdown voltage buffer 20-j in FIG. 2.

The level shift circuit 10-j includes P-type MOS transistors 11 and, 13 and N-type MOS transistors 12 and 14. The high breakdown voltage buffer 20-j includes a P-type MOS transistor 21 and an N-type MOS transistor 22. As described above, the capacitor element 2 is connected to the output of the high breakdown voltage buffer 20-j from the data output node OUTj via the data electrode Dj. The data driver 5 further includes inverters 15, 16.

The P-type transistors 11 and 13 are connected to the power supply output node NVDD2. The N-type transistor 12 is connected to a gate of the P-type transistor 13 and the P-type transistor 11, and the power supply NGND which supplies a ground voltage GND, and the output from the output control circuit 6 is supplied to the gate of the N-type transistor 12. The inverter 15 inverts the output from the output control circuit 6. The inverter 16 inverts an output from the inverter 15. The N-type transistor 14 is connected to a gate of the P-type transistor 11, and the P-type transistor 13 and a gate of the P-type transistor 21, and the power supply NGND and the output from the inverter 15 is supplied to the gate the N-type transistor 14. The P-type transistor 21 is connected to the power supply output node NVDD2 and the data output node OUTj and the output from the level shift circuit 10-j is supplied to the gate of the P-type transistor 21. The P-type transistor 21 is turned on when a signal level of an output signal outputted from the level shift circuit 10-j is in a low level, and is turned off when the signal level of the output signal is in a high level. The N-type transistor 22 is connected to the data output node OUTj and the power supply NGND, and the output from the inverter 16 is supplied to the gate of the N-type transistor 22. The N-type transistor 22 is turned off when a signal level of an output signal outputted from the inverter 16 is in the low level, and is turned on when the signal level of the output signal is in the high level.

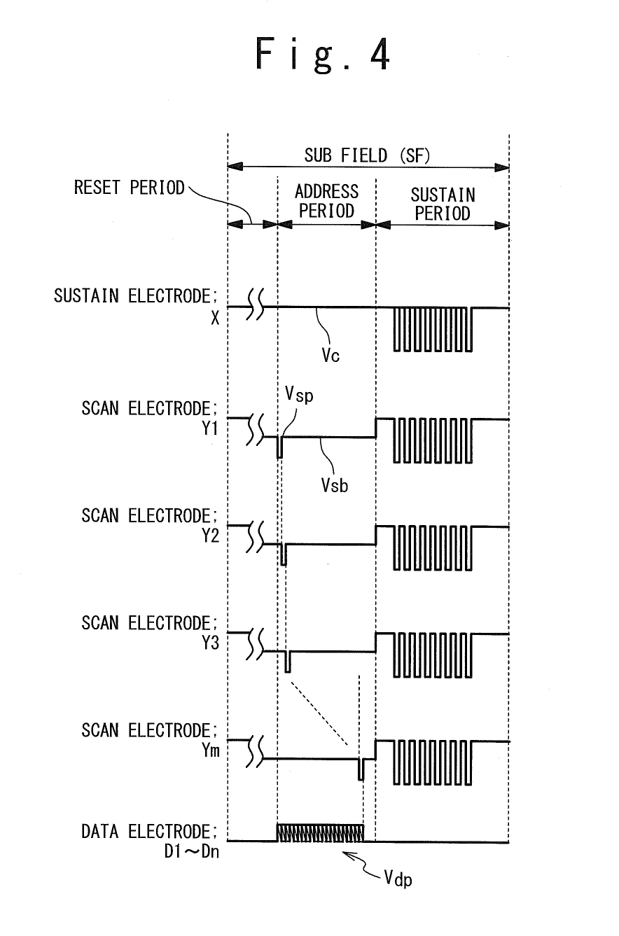

FIG. 4 shows timing charts in an operation of the plasma display apparatus. Here, one field or one subfield includes a reset period, an address period after the reset period and a sustain period after the address period.

In the reset period, the control section 7 controls the sustain driver 3 and the scan driver 4 to supply voltages to the plurality of sustain electrodes X and the plurality of scan electrodes Y1 to Ym, to adjust electric charges accumulated when a sustain discharge is performed between the plurality of sustain electrodes X and the plurality of scan electrodes Y1 to Ym.

In the address period, the control section 7 controls the sustain driver 3, the scan driver 4 and the data driver 5 to supply voltages to the plurality of the sustain electrodes X, the plurality of scan electrodes Y1 to Ym and the plurality data electrodes D1 to Dn, to perform a write discharge between the plurality of scan electrodes Y1 to Ym and the plurality of data electrodes D1 to Dn to write image data to the display cells 2. For example, the control section 7 controls the sustain driver 3 to supply a first setting voltage Vc to the plurality of sustain electrodes X. The control section 7 controls the scan driver 4 to supply a second setting voltage Vs higher than the ground voltage GND to the plurality of scan electrodes Y1 to Ym and thereafter supply a scan pulse voltage Vsp to the plurality of scan electrodes Y1 to Ym in the order from the first scan electrode to the last electrode. The scan pulse voltage Vsp decreases from the second setting voltage Vs to the ground voltage GND. The control section 7 controls the data driver 5 to supply a data pulse voltage Vdp corresponding to the image data, which represents images, to the plurality of the data electrodes D1 to Dn. At this time, in the data driver 5, the output control circuit 6 firstly converts the scan pulse voltage Vsp into the data pulse voltage Vdp corresponding to the image data through the control by the control section 7. Then, the plurality of level shift circuits 10-1 to 10-n convert a level of the data pulse voltage into a write voltage level to the display cells 2. Subsequently, the plurality of high breakdown voltage buffers 20-1 to 20-n output the data pulse voltages Vdp from the plurality of level shift circuits 10-1 to 10-n to the plurality of data electrodes D1 to Dn, respectively.

The control section 7 also recovers electric charges (power) which are accumulated at the time of light emission of the display cell 2 when the display cell 2 does not emit light and then reuses the recovered power when the display cell 2 emits light. For this purpose, in the address period, the control section 7 controls the power recovery circuit 30 to recover the power accumulated in the display cell 2.

In the sustain period, the control section 7 controls the sustain driver 3 and the scan driver 4 to supply the voltages to the plurality of sustain electrodes X and the plurality of the scan electrodes Y1 to Ym, to perform the sustain discharge for causing the display cells 2 to which the write discharge has been performed to emit light between the plurality of the scan electrodes Y1 to Ym and the plurality of sustain electrodes X, respectively.

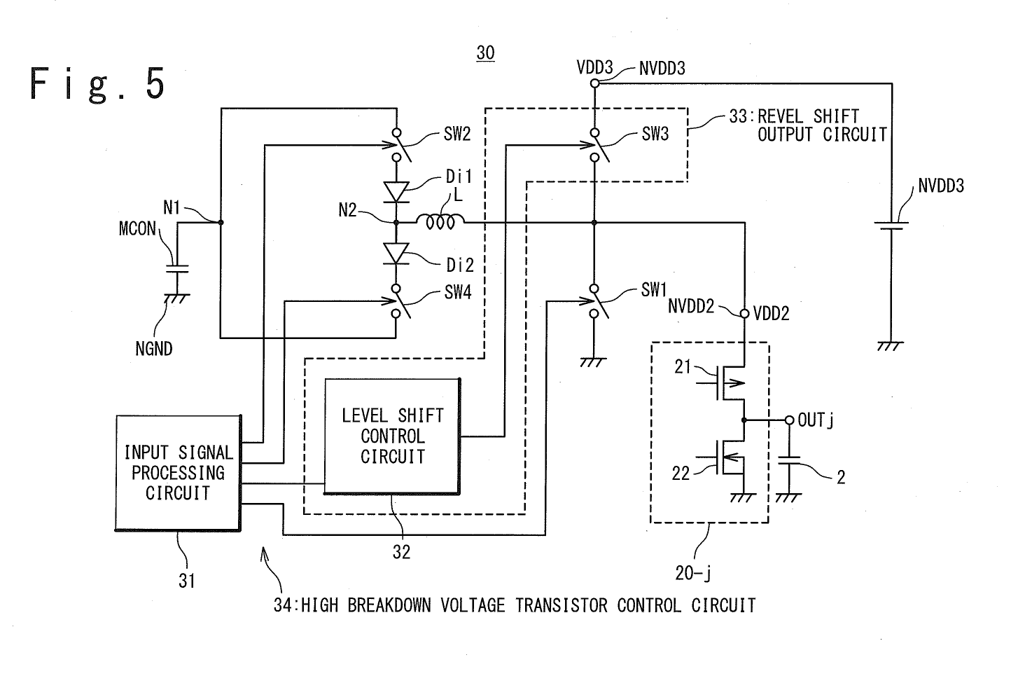

FIG. 5 illustrates a configuration of the power recovery circuit 30 in FIG. 1. The power recovery circuit 30 includes a capacitance element MCON for power recovery, an inductance element L, an first diode Di1, a second diode Di2, a first switch SW1, a second switch SW2, a fourth switch SW4 and a high breakdown voltage transistor control circuit 34. The high breakdown voltage transistor control circuit 34 includes an input signal processing circuit 31 and a level shift output circuit 33. The level shift output circuit 33 includes a level shift control circuit 32 and a third switch SW3.

The capacitance element MCON for power recovery is connected between a first node N1 and the power supply NGND. The inductance element L is connected between a second node N2 and the power supply output node NVDD2. A cathode of the first diode Di1 is connected to the second node N2. An anode of the second diode Di2 is connected to the second node N2. The first switch SW1 is connected between the power supply output node NVDD2 and the power supply NGND. The second switch SW2 is connected between the first node N1 and an anode of the first diode Di1. The third switch SW3 is connected between a power supply NVDD3 and the power supply output node NVDD2. The fourth switch SW4 is connected between the first node N1 and a cathode of the second diode Di2.

The power supply NVDD3 supplies a first voltage VDD3. The power supply NGND supplies the abovementioned ground voltage GND which is a second voltage lower than the first voltage VDD3. Hereinafter, the power supply NVDD3 and the power supply NGND are referred to as a first power supply NVDD3 and a second power supply NGND, respectively.

The input signal processing circuit 31 is connected to the first to fourth switches SW1 to SW4. In the address period, the input signal processing circuit 31 turns on the first to fourth switches SW1 to SW4 in this order through the control by the control section 7.

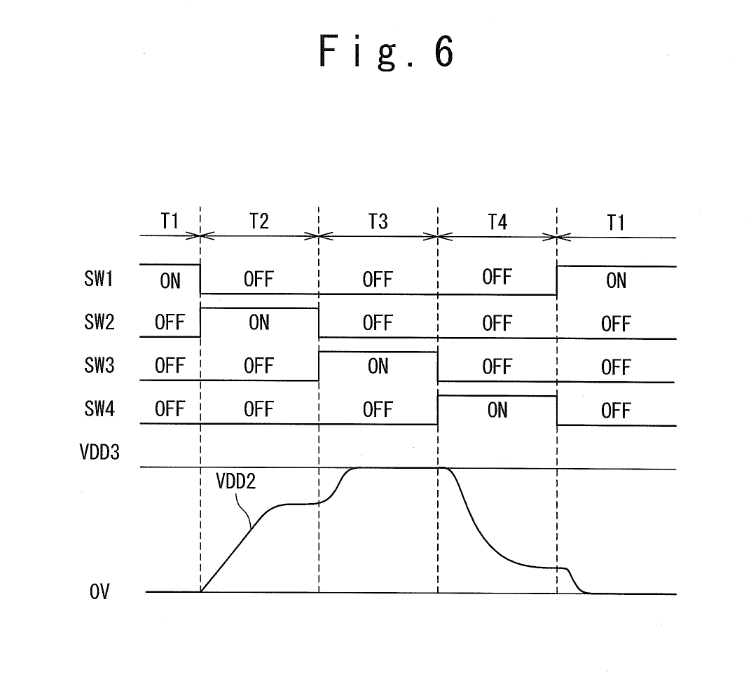

FIG. 6 shows timing charts in an operation of the power recovery circuit 30 in FIG. 5. In the address period, the input signal processing circuit 31 performs processing during a first period T1 to a fourth period T4. The first, second and fourth switches SW1, SW2 and SW4 are turned on in response to first ON control signals “ON” and are turned off in response to first OFF control signals “OFF”. The third switch SW3 is turned on in response to a second ON control signal “ON” and turned off in response to a second OFF control signal “OFF”.

During the first period T1, the input signal processing circuit 31 set a first mode by outputting the first ON control signal “ON” to the first switch SW1, output the first OFF control signals “OFF” to the second and fourth switches SW2 and SW4. In the first mode, the input signal processing circuit 31 outputs the second OFF control signal “OFF” to the third switch SW3 via the level shift control circuit 32. In this case, the first switch SW1 is turned on in response to the first ON control signal “ON”, the second and fourth switches SW2 and SW4 are turned off in response to the first OFF control signals “OFF”, and the third switch SW3 is turned off in response to the second OFF control signal “OFF”. When the first switch SW1 is turned on, electric charges accumulated in the capacitance element (display cell) is discharged.

During the second period T2 following the first period T1, the input signal processing circuit 31 outputs the first ON control signal “ON” to the second switch SW2, the first OFF control signals “OFF” to the first and fourth switches SW1 and SW4, and outputs the second OFF control signal “OFF” to the third switch SW3 via the level shift control circuit 32 as the execution of the first mode. In this case, the second switch SW2 is turned on in response to the first ON control signal “ON”, the first and fourth switches SW1 and SW4 are turned off in response to the first OFF control signals “OFF”, and the third switch SW3 is turned off in response to the second OFF control signal “OFF”. When the second switch SW2 is turned on, the electric charges accumulated in the capacitance element MCON for power recovery are supplied to the capacitance element 2 through the second switch SW2, the first diode Di1, the inductance element L, the power supply output node NVDD2 and the high breakdown voltage buffer 20-j.

During the third period T3 following the second period T2, the input signal processing circuit 31 sets a second mode by outputting the first OFF control signals “OFF” to the first, second and fourth switches SW1, SW2 and SW4. In the second mode, the input signal processing circuit 31 outputs the second ON control signal “ON” to the third switch SW3 via the level shift control circuit 32. In this case, the first, second and fourth switches SW1, SW2 and SW4 are turned off in response to the first OFF control signals “OFF” and the third switch SW3 is turned on in response to the second ON control single “ON”. When the third switch SW3 is turned on, the first voltage VDD3 is supplied to the power supply output node NVDD2.

During the fourth period T4 following the third period T3, the input signal processing circuit 31 outputs the first ON control signal “ON” to the fourth switch SW4, and the first OFF control signals “OFF” to the first and second switches SW1 and SW2, and outputs the second OFF control signal “OFF” to the third switch SW3 via the level shift control circuit 32 as the execution of the first mode. In this case, the fourth switch SW4 is turned on in response to the first ON control signal “ON”, the first and second switches SW1 and SW2 are turned off in response to the first OFF control signals “OFF”, and the third switch SW3 is turned off in response to the second OFF control signal “OFF”. When the fourth switch SW4 is turned on, the electric charges accumulated in the capacitance element 2 are transferred to and accumulated in the capacitance element MCON for power recovery via the high breakdown voltage buffer 20-j, the power supply output node NVDD2, the inductance element L, the second diode Dig and the fourth switch SW4.

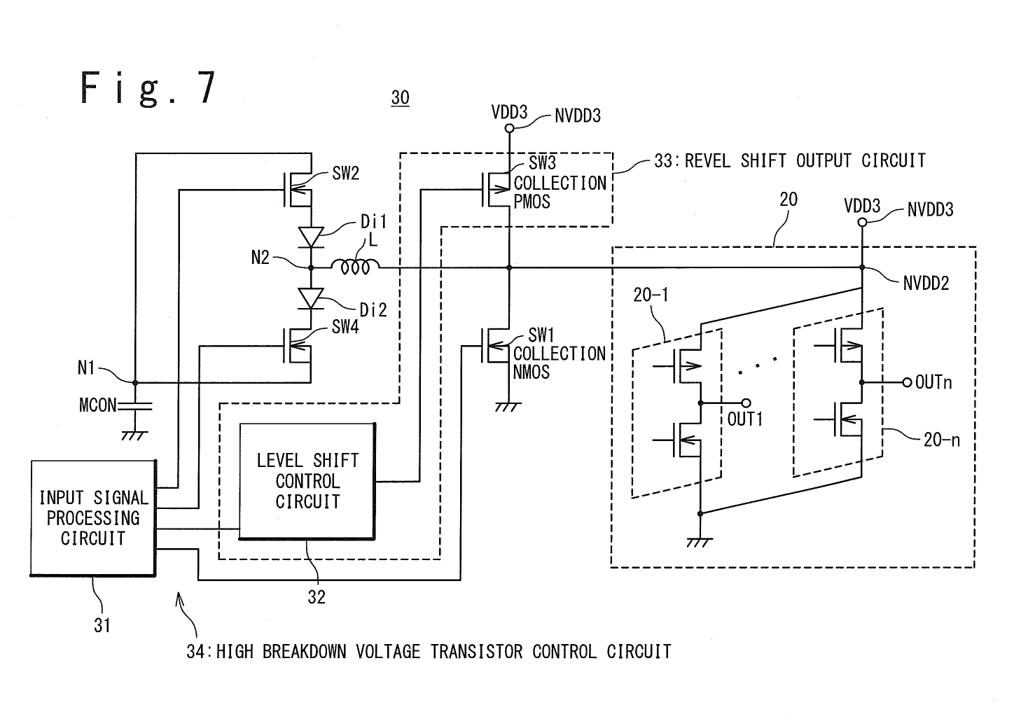

FIG. 7 illustrates a specific example of the first switch SW1, the second switch SW2, the third switch SW3 and the fourth switch SW4 in FIG. 5. The first, second and fourth switches SW1, SW2 and SW4 are N-type MOS transistors. In this case, a signal level of the first ON control signal “ON” is in the high level and the signal level of the first OFF control signal “OFF” is in the low level.

The third switch SW3 is a high breakdown voltage P-type transistor. In this case, the signal level of the second ON control signal “ON” is in the low level and the signal level of the second OFF control signal “OFF” is in the high level.

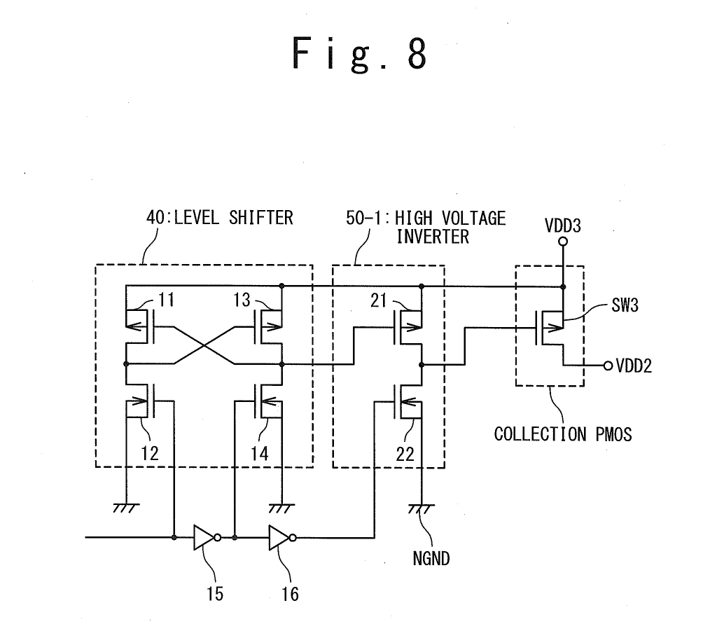

FIG. 8 illustrates a configuration of a general level shift output circuit. The general level shift output circuit includes a level shifter 40, a high breakdown voltage inverter 50-1, and the third switch SW3 (a high breakdown voltage P-type transistor), as mentioned above.

The level shifter includes first and second P-type transistors and first and second N-type transistors. The high breakdown voltage inverter includes a P-type transistor and an N-type transistor.

In the level shifter, first and second P-type transistors 11 and 13 are connected to the first power supply NVDD3. A first N-type transistor 12 is connected to a gate of the second P-type transistor 13, the first P-type transistor 11 and the second power supply NGND, and an input signal is supplied to the gate of the first N-type transistor 12. The second N-type transistor 14 is connected to a gate of the first P-type transistor 11, the second P-type transistor 13 and a gate of the P-type transistor 21 of the high breakdown voltage inverter and the second power supply NGND, and the input signal is supplied to the gate of the transistor 14.

The P-type transistor 21 of the high breakdown voltage inverter is connected between the first power supply NVDD3 and a gate of the third switch SW3. The N-type transistor 22 of the high breakdown voltage inverter is connected between an input of the third switch SW3 (the gate of the high breakdown voltage P-type transistor) and the second power supply NGND. Thus, an output of the high breakdown voltage inverter is connected to the input of the third switch SW3.

The high breakdown voltage P-type transistor of the third switch SW3 is required to have a high breakdown voltage (approximately 60 V to 100 V) and high current capacity (approximately several A to 10 A). For example, if a sufficient current may not flow due to the restriction on an inspection apparatus in a step for inspecting a characteristic of the third switch SW3, a detection rate of defects is lowered.

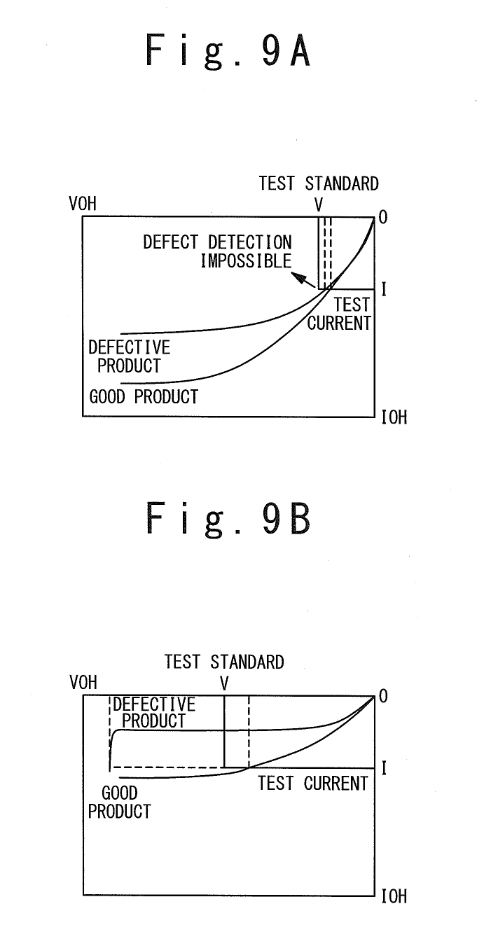

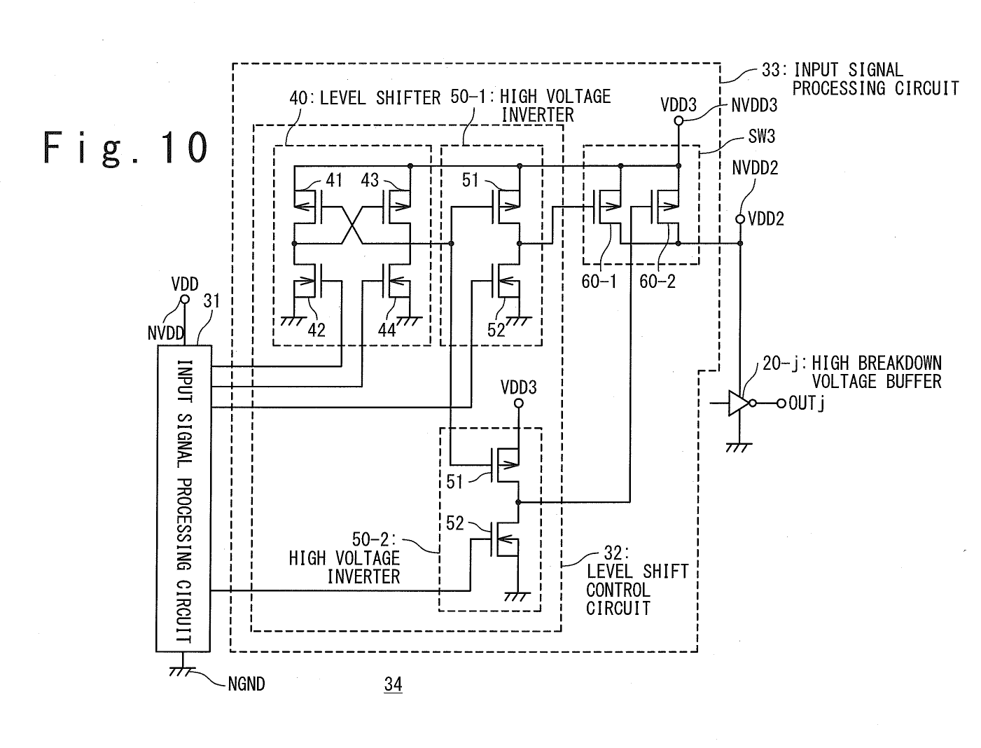

FIG. 9A shows a detection rate of defects when the third switch SW3 in FIG. 8 includes a single high breakdown voltage P-type transistor. In this case, a current of the high breakdown voltage P-type transistor is larger than a current defined by the restriction of the inspection apparatus and the detection rate of defects is lowered. FIG. 9B shows a detection rate of defects when the third switch SW3 in FIG. 8 includes two high breakdown voltage P-type transistors in parallel. In this case, the current capacity is distributed by arranging the plurality of high breakdown voltage P-type transistors in parallel. Accordingly, a current flowing through the high breakdown voltage P-type transistor is within the current defined through the restriction of the inspection apparatus, thereby the detection rate of defects is not lowered.

As described later, in the level shift output circuit according to the present embodiment of the present invention, the current capacity is distributed by arranging the plurality of high breakdown voltage P-type transistors in parallel as the third switch SW3. In such a case, in the Patent Literature 1, a level shift output circuit includes a plurality of level shifters, a plurality of high breakdown voltage inverters and a plurality of switches (high breakdown voltage P-type transistors). However, in the present invention, a level shift output circuit includes a single level shifter, a plurality of high breakdown voltage inverters and a plurality of switches (high breakdown voltage P-type transistors). Thus, in the present invention, there is no increase of an area due to the level shifters compared to the conventional technique. There is no increase of power consumed in the level shifter. Hereinafter, the level shift output circuit which realizes such effects will be described in detail.

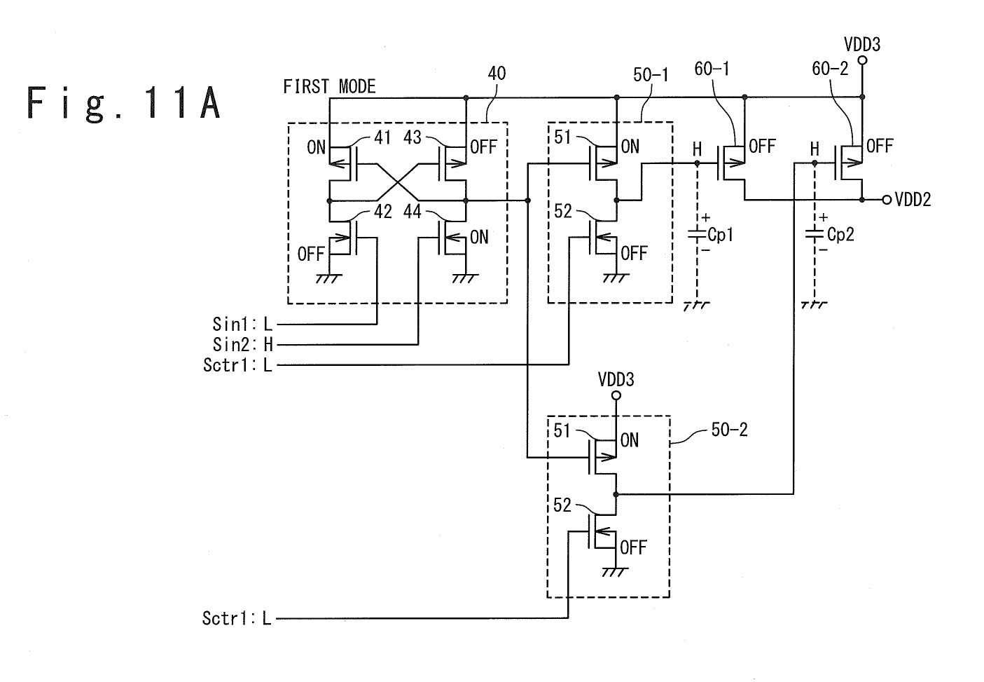

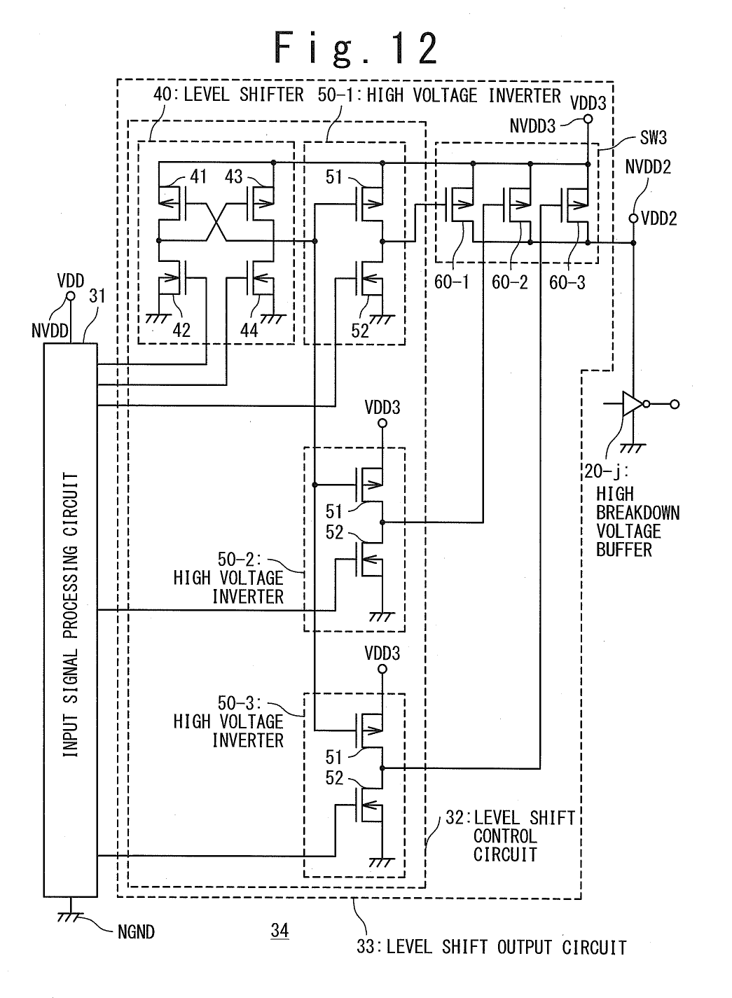

FIGS. 10 and 12 illustrate configurations of the level shift output circuit 33 in the power recovery circuit 30 in FIG. 5 as the level shift output circuit according to the present embodiment of the present invention.

As described above, the level shift output circuit 33 is connected to the input signal processing circuit 31. The input signal processing circuit 31 is connected between a reference power supply NVDD and the second power supply NGND. The reference power supply NVDD supplies the reference voltage VDD which is lower than the first voltage VDD3 and higher than the second voltage GND. The input signal processing circuit 31 uses the reference voltage VDD as a power supply.

As described above, the level shift output circuit 33 includes a level shift control circuit 32 and the third switch SW3. The third switch SW3 includes a plurality of high breakdown voltage P-type transistors 60-1 to 60-z (z represents an integer equal to or more than 2). The plurality of high breakdown voltage P-type transistors 60-1 to 60-z are connected between the first power supply NVDD3 and the second power supply output node NVDD2.

The level shift control circuit 32 includes a level shifter 40 and a plurality of high breakdown voltage inverters 50-1 to 50-z. The level shifter 40 and the plurality of high breakdown voltage inverters 50-1 to 50-z are connected between the first power supply NVDD3 and the second power supply NGND.

The level shifter 40 includes a first P-type transistor 41, a first N-type transistor 42, a second P-type transistor 43 and a second N-type transistor 44. Each of the plurality of high breakdown voltage inverters 50-1 to 50-z includes a P-type transistor 51 and an N-type transistor 52.

The first P-type transistor 41 and the second P-type transistor 43 are connected to the first power supply NVDD3. The first N-type transistor 42 is connected to the first P-type transistor 41 and the second power supply NGND and the input signal processing circuit 31 is connected to the gate of the transistor 42. A gate of the second P-type transistor 43 is connected to the node between the first P-type transistor 41 and the first N-type transistor 42. The second N-type transistor 44 is connected to the second P-type transistor 43 and the second power supply NGND, and the input signal processing circuit 31 is connected to the gate of the transistor 44. A gate of the P-type transistor 51 and a gate of the N-type transistor 52 in each of the plurality of the high breakdown voltage inverters 50-1 to 50-z are connected to the gate of the first P-type transistor 41 and a node between the second P-type transistor 43 and the second N-type transistor 44.

The P-type transistors 51 in the plurality of high breakdown voltage inverters 50-1 to 50-z are connected to the first power supply NVDD3 and gates of the plurality of high breakdown voltage P-type transistors 60-1 to 60-z, respectively. The N-type transistors 52 in the plurality of high breakdown voltage inverters 50-1 to 50-z are connected to the gates of the plurality of high breakdown voltage P-type transistors 60-1 to 60-z and the second power supply NGND, respectively. Thus, the outputs of the plurality of high breakdown voltage inverters 50-1 to 50-z are connected to the gates of the plurality of high breakdown voltage P-type transistors 60-1 to 60-z, respectively.

FIG. 10 shows a case that z is 2. FIG. 12 shows a case that z is 3. Hereinafter, an operation of the high breakdown voltage transistor control circuit 34 will be described by taking the case that z is 2, as an example.

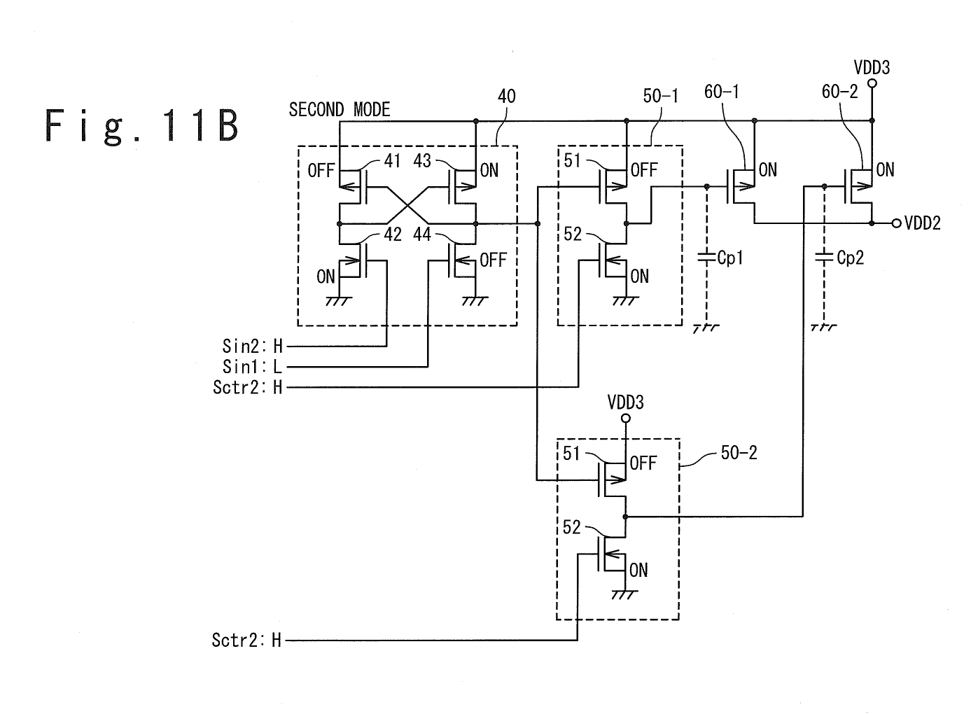

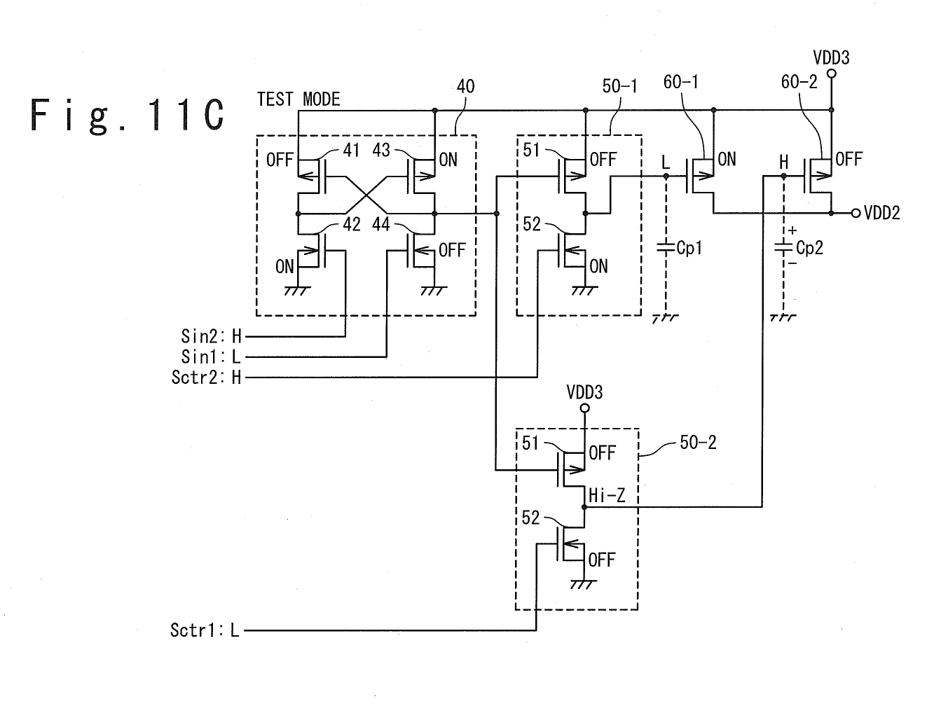

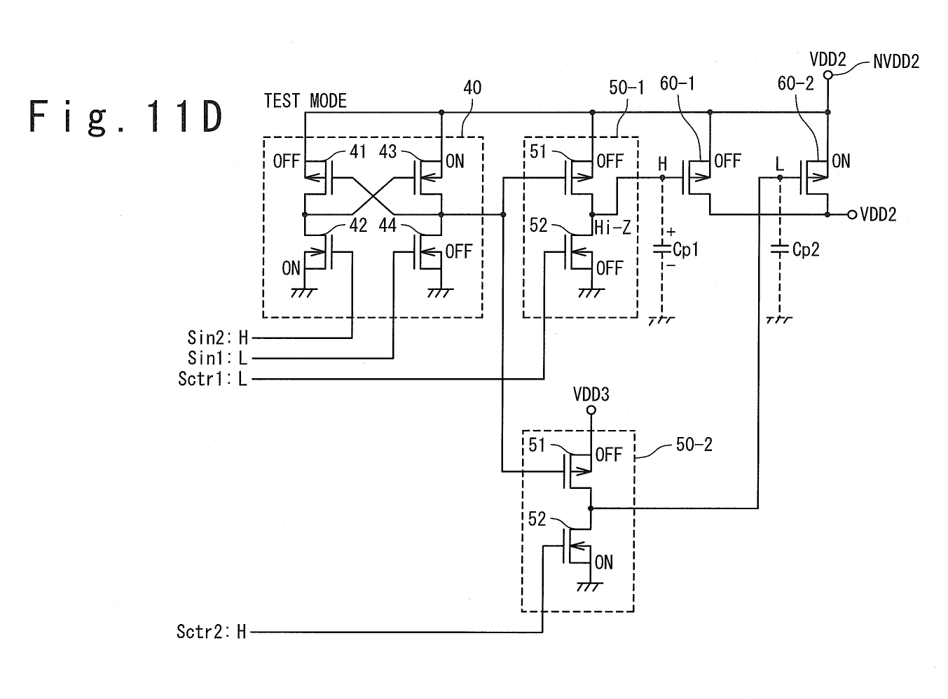

FIG. 11A illustrates the operation of the level shift output circuit 33 according to the present embodiment of the present invention in the first mode.

In a first period T1, a second period T2 and a fourth period T4 in the first mode, the input signal processing circuit 31 outputs a first input signal Sin1 “L” to the gate of the first N-type transistor 42 in the level shifter 40, outputs a second input signal Sin1 “H” to the gate of the second N-type transistor 44 in the level shifter 40 and outputs the first control signal Sctr1 “L” to the gate of the N-type transistor 52 in each of the plurality of high breakdown voltage inverters 50-1 to 50-2.

In this case, the level shifter 40 outputs the first output signal “L” to the gates of the P-type transistors 51 in the plurality of high breakdown voltage inverters 50-1 to 50-2 in response to the first input signal Sin1 “L”.

The plurality of high breakdown voltage inverters 50-1 to 50-2 output third output signals “H” in response to the first control signal Sctr1 “L” and the first output signal “L” from the level shifter 40. The third output signal “H” is outputted as the output signal from the level shift control circuit 32 and corresponds to the second ON control signal “H” mentioned above.

The plurality of high breakdown voltage P-type transistors 60-1 to 60-2 are turned off in response to the third output signals “H” from the plurality of high breakdown voltage inverters 50-1 to 50-2, respectively.

FIG. 11B illustrates the operation of the level shift output circuit 33 according to the embodiment of the present invention in a second mode.

In the third period T3, the input signal processing circuit 31 outputs the second input signal Sin2 “H” to the gate of the first N-type transistor 42 in the level shifter 40, outputs the first input signal Sin1 “L” to the gate of the second N-type transistor 44 in the level shifter 40 and outputs a second control signal Sctr2 “H” to the gate of the N-type transistor 52 in the plurality of high breakdown voltage inverters 50-1 to 50-2 as the execution of the second mode.

In this case, the level shifter 40 outputs the second input signal “H” to the gate of the P-type transistor 51 in the plurality of high breakdown voltage inverters 50-1 to 50-2 in response to the second input signal Sin2 “H”. The plurality of the high breakdown voltage inverters 50-1 to 50-2 output a fourth output signal “L” having a reverse polarity against the third output signal “H” in response to the second control signal Sctr2 “H” and the second output signal “H” from the level shifter 40. The fourth output signal “L” is outputted as the output signal of the level shift control circuit 32 and corresponds to the second OFF control signal “L” described above.

The plurality of high breakdown voltage P-type transistors 60-1 to 60-2 are turned on respectively in response to the fourth output signals “L” from the plurality of high breakdown voltage inverters 50-1 to 50-2 to supply the first voltage VDD3 to the power supply output node NVDD2.

Parasitic capacitances exist at the gates of the high breakdown voltage P-type transistors 60-1 to 60-2. The parasitic capacitance Cp1 at the high breakdown voltage P-type transistor 60-1 and the parasitic capacitance Cp2 at the high breakdown voltage P-type transistor 60-2 are charged with electric charges which are positive on the side of the gate, in the first mode. In this state, when the high breakdown voltage inverters 50-1 to 50-2 exhibits a Hi-Z (high impedance) state, the parasitic capacitances Cp1 to Cp2 maintain the positive voltages sufficient to keep the off state of the high breakdown voltage P-type transistors 60-1 to 60-2 during a time period defined based on the electric charges amount and leakage current. Needless to say, there should not be any problems due to the parasitic capacitances Cp1 to Cp2 in the operation of the level shift output circuit 33 if the electric charges of the parasitic capacitances Cp1 to Cp2 are respectively discharged by the abilities of the high breakdown voltage inverters 50-1 to 50-2.

FIGS. 11C and 11D illustrate the operation of the level shift output circuit 33 according to the embodiment of the present invention in a test mode. In order to test each of the plurality of high breakdown voltage P-type transistors 60-1 to 60-2, the input signal processing circuit 31 sets a test mode under the control by the control section 7 or an instruction from an examiner.

In the test mode, the input signal processing circuit 31 outputs the second input signal Sint “H” to the gate of the first N-type transistor 42 in the level shifter 40 and outputs the first input signal Sin1 “L” to the gate of the second N-type transistor 44 in the level shifter 40. At this time, the input signal processing circuit 31 outputs the second control signal Sctr2 “H” to each of the plurality of high breakdown voltage inverters 50-1 to 50-2 in the order from the first inverter to the last inverter, and outputs the first control signal Sctr1 “L” to the high breakdown voltage inverters other than the high breakdown voltage inverter 50-k (k represents an integer satisfying 1·k·2) to which the second control signal Sctr2 “H” is supplied.

Specifically, in the test mode, the operation in the first mode is performed and then a first test mode is performed, as shown in FIG. 11C. Thereafter, the first mode is performed again and then a second test mode is performed, as shown in FIG. 11D.

In the first test mode, the input signal processing circuit 31 outputs the second input signal Sin2 “H” to the gate of the first N-type transistor 42 in the level shifter 40 and outputs the first input signal Sin1 “L” to the gate of the second N-type transistor 44 in the level shifter 40. At this time, the input signal processing circuit 31 outputs the second control signal Sctr2 “H” to the high breakdown voltage inverter 50-1 and outputs the first control signal Sctr1 “L” to the high breakdown voltage inverter 50-2.

In the second test mode, the input signal processing circuit 31 outputs the second input signal Sin2 “H” to the gate of the first N-type transistor 42 in the level shifter 40 and outputs the first input signal Sin1 “L” to the gate of the second N-type transistor 44 in the level shifter 40. At this time, the input signal processing circuit 31 outputs the first control signal Sctr1 “L” to the high breakdown voltage inverter 50-1 and outputs the second control signal Sctr2 “H” to the high breakdown voltage inverter 50-2.

Here, the operation in the first mode is performed immediately before the first test mode or the second test mode, and the signal supplied to the gates of the high breakdown voltage P-type transistors 60-1 to 60-2 is set to the high level, thereby charging the parasitic capacitances Cp1 to Cp2. Subsequently, the control signals to be supplied to the level shifter 40 and the N-type transistors 52 in the high breakdown voltage inverters 50-1 to 50-2 are inverted from the first control signal Sctr1 “L” to the second control signal Sctr2 “H”, thereby the first test mode or the second test mode are set. At this time, the output of the high breakdown voltage inverter (e.g., high breakdown voltage inverter 50-2) is set to high impedance (Hi-Z) state, and the first control signal Sctr1 “L” is supplied to the N-type transistor 52 of the above inverter among the high breakdown voltage inverters 50-1 to 50-2. However, because of the electric charges accumulated in the parasitic capacitance (in this case, the parasitic capacitance Cp2) at the gate of the high breakdown voltage P-type transistor (in this case, the high breakdown voltage P-type transistor 60-2), the control signal supplied to the gate of the high breakdown voltage P-type transistor 60-2 is maintained at the high level within a time period defined based on the relation of the parasitic capacitance and leak resistance, so that the OFF state of the high breakdown voltage P-type transistor 60-2 is maintained.

Referring to the above description, in the level shift output circuit 33 according to the present embodiment of the present invention, the plurality of high breakdown voltage P-type transistors 60-1 to 60-z in parallel are arranged as the third switch SW3, to distribute the current capacity. In such a case, in the conventional example, a level shift output circuit includes a plurality of level shifters, a plurality of high breakdown voltage inverters and a plurality of switches (high breakdown voltage P-type transistors). However, in the present invention, the level shift output circuit includes the single level shifter 40, the plurality of high breakdown voltage inverters 50-1 to 50-z and the plurality of switches (high breakdown voltage P-type transistors 60-1 to 60-z). Thus, in the present invention, there is no increase of the area due to the level shifter compared to the conventional example.

In addition, in the level shift output circuit 33 according to the present embodiment of the present invention, since there is no increase of the chip area due to the lever shifter, the power consumed by the level shifter does not increase. In the conventional example, as the number of level shifters increases, the power consumption amount increases even if the current capacity of the high breakdown voltage P-type transistor is distributed. This is a fatal problem in the power recovery. The present invention can avoid such the problem.

In addition, in the level shift output circuit 33 according to the present embodiment of the present invention, since the N-type transistors can be controlled independently by the input signal processing circuit 31, the test of the high breakdown voltage P-type transistor 60-1 to 60-z can be performed with high reliability in the test mode.

Here, the level shift output circuit 33 according to the present embodiment of the present invention can be applied to a high breakdown voltage output buffer circuit. The description duplicated the abovementioned description is omitted here.

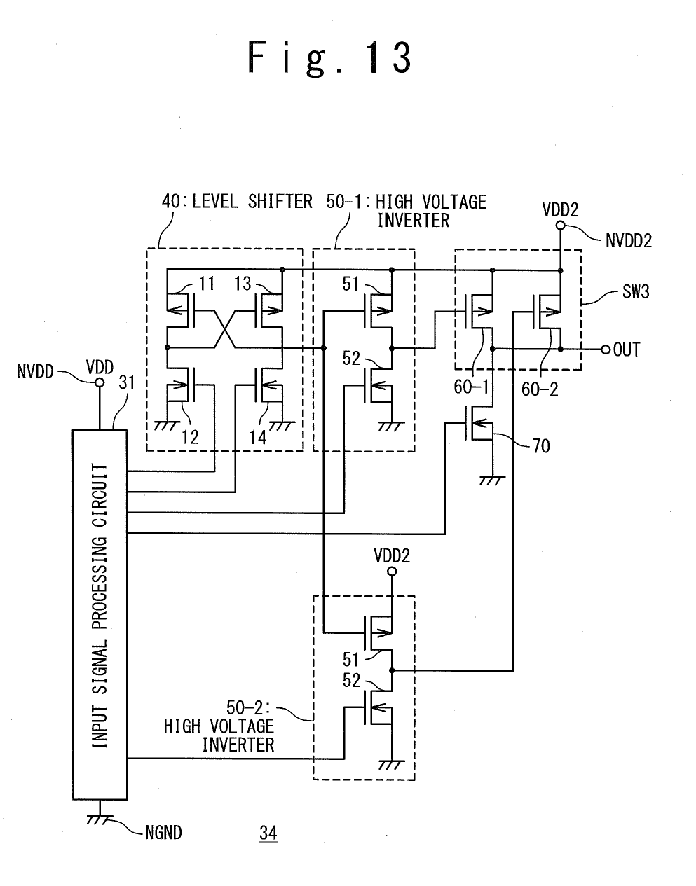

In this case, as illustrated in FIG. 13, the level shift output circuit 33 according to the present embodiment of the present invention further includes an N-type transistor 70 for the buffer. The N-type transistor 70 is connected between the plurality of high breakdown voltage P-type transistors 60-1 to 60-z and the second power supply NGND.

It is assumed that instead of the above-mentioned first power supply NVDD3, a first power supply is the power supply NVDD2 corresponding to the above-mentioned power supply output node NVDD2. It is assumed that instead of the above-mentioned first voltage VDD3, a first voltage is a voltage NVDD2. It is assumed that instead of the abovementioned power supply output node NVDD2, a power supply output node is a data output node OUT. In this case, the level shifter 40 is connected between the first power supply NVDD2 and the second power supply NGND. The first power supply NVDD2 supplies the voltage VDD2 higher than the reference voltage VDD. The plurality of high breakdown voltage inverters 50-1 to 50-z are connected between the first power supply NVDD2 and the second power supply NGND. The plurality of high breakdown voltage P-type transistors 60-1 to 60-z are connected between the first power supply NVDD2 and the power supply output node OUT.

In the first mode, the N-type transistor 70 is turned on in response to the third input signal “H” from the input signal processing circuit 31. The third input signal is in the high level. The other features are the same as the forgoing embodiment.

In the second mode, if the fourth output signal “L” from the plurality of high breakdown voltage inverters 50-1 to 50-z is respectively supplied to the plurality of high breakdown voltage P-type transistors 60-1 to 60-z when the N-type transistor 70 is turned off, the plurality of high breakdown voltage P-type transistors 60-1 to 60-z supply the first voltage VDD2 to the power supply output node OUT. The other features are the same as the forgoing embodiment.

In addition, in the test mode, the other features are the same as the above embodiment.

As described above, the plurality of high breakdown voltage P-type transistors 60-1 to 60-z and the N-type transistor 70 for the buffer can be used as a high breakdown voltage buffer circuit.

Although the present invention has been described above in connection with several embodiments thereof, it would be apparent to those skilled in the art that those embodiments are provided solely for illustrating the present invention, and should not be relied upon to construe the appended claims in a limiting sense.

What is claimed is:

1. A level shift output circuit comprising:
a level shifter connected between a first power supply which supplies a first voltage and a second power supply which supplies a second voltage which is lower than the first voltage, and configured to output a first output signal in response to a first input signal, and output a second output signal which is complimentary with said first output signal, in response to a second input signal which is complimentary with said first input signal;
a plurality of high breakdown voltage inverters connected between said first power supply and said second power supply, and configured to output a third output signal in response to a first control signal and said first output signal from said level shifter and output a fourth output signal which is complimentary with said third output signal, in response to a second control signal which is complimentary with said first control signal, and said second output signal from said level shifter; and
a plurality of P-type transistors connected between said first power supply and a power supply output node, and configured to respectively supply said first voltage to said power supply output node in response to said fourth output signals from said plurality of high breakdown voltage inverters.

2. The level shift output circuit according to claim 1, wherein outputs of said plurality of high breakdown voltage inverters are respectively connected with gates of said plurality of high breakdown voltage transistors, and
wherein said plurality of high breakdown voltage P-type transistors are respectively turned off in response to said third output signals from said plurality of high breakdown voltage inverters, and are respectively turned on in response to said fourth output signals from said plurality of high breakdown voltage inverters to supply said first voltage to said power supply output node.

3. The level shift output circuit according to claim 2, wherein each of said plurality of high breakdown voltage inverters comprises a P-type transistor and an N-type transistor,
wherein said P-type transistor of each of said plurality of high breakdown voltage inverters is connected between said first power supply and a gate of a corresponding one of said plurality of high breakdown voltage P-type transistors, and said first output signal or said second output signal is supplied from said level shifter to a gate of said P-type transistor,
wherein said N-type transistor of each of said plurality of high breakdown voltage inverters is connected between said second power supply and a gate of a corresponding one of said plurality of high breakdown voltage P-type transistors and said first control signal or said second control signal is supplied to a gate of said N-type transistor, and
wherein said first output signal and said first control signal are in the low level, and said second output signal and said second control signal are in the high level.

4. The level shift output circuit according to claim 3, wherein said level shifter comprises:
a first P-type transistor connected with said first power supply;
a second P-type transistor connected with said first power supply;
a first N-type transistor connected between said first P-type transistor and said second power supply, and having a gate supplied with said first input signal or said second input signal; and
a second N-type transistor connected between said second P-type transistor and said second power supply, and having a gate supplied with said second input signal or said first input signal, and
wherein a gate of said second P-type transistor is connected with a node between said first P-type transistor and said first N-type transistor, and a gate of said first P-type transistor and gates of said P-type transistors of said plurality of high breakdown voltage inverters are connected with a node between said second P-type transistor and said second N-type transistor.

5. The level shift output circuit according to claim 1, further comprising:
a buffer N-type transistor connected between said plurality of high breakdown voltage P-type transistors and said second power supply and turned on in response to said third input signal,
wherein said plurality of high breakdown voltage P-type transistors and said buffer N-type transistor are used as a high breakdown voltage buffer, and
wherein said plurality of high breakdown voltage P-type transistors supplies said first voltage to said power supply output node when said fourth output signals are respectively supplied from said plurality of high breakdown voltage inverters in a state that said buffer N-type transistor is turned off.

6. A high breakdown voltage transistor control circuit comprising:
a level shift output circuit which comprises:
a level shifter connected between a first power supply which supplies a first voltage and a second power supply which supplies a second voltage which is lower than the first voltage, and configured to output a first output signal in response to a first input signal, and output a second output signal which is complimentary with said first output signal, in response to a second input signal which is complimentary with said first input signal,
a plurality of high breakdown voltage inverters connected between said first power supply and said second power supply, and configured to output a third output signal in response to a first control signal and said first output signal from said level shifter and output a fourth output signal which is complimentary with said third output signal, in response to a second control signal which is complimentary with said first control signal, and said second output signal from said level shifter; and
a plurality of P-type transistors connected between said first power supply and a power supply output node, and configured to respectively supply said first voltage to said power supply output node in response to said fourth output signals from said plurality of high breakdown voltage inverters; and
an input signal processing circuit configured to execute a process in a first mode to output said first input signal to said level shifter in said level shift output circuit, and output said first control signal to said plurality of high breakdown voltage inverters in said level shift output circuit, and execute a process in a second mode to output said second input signal to said level shifter and output said second control signal to said plurality of high breakdown voltage inverters.

7. The high breakdown voltage transistor control circuit according to claim 6, wherein said input signal processing circuit executes a process in a test mode after said first mode when each of said plurality of high breakdown voltage P-type transistors is tested, and
said input signal processing circuit executes the process in said test mode to output said second input signal to said level shifter, output said second control signal to each of first to last ones of said plurality of high breakdown voltage inverters in that order, and output said first control signal to said plurality of high breakdown voltage inverters other than said high breakdown voltage inverter to which said second control signal is supplied.

8. A power recovery circuit comprising:
a level shift output circuit which comprises:
a level shifter connected between a first power supply which supplies a first voltage and a second power supply which supplies a second voltage which is lower than the first voltage, and configured to output a first output signal in response to a first input signal, and output a second output signal which is complimentary with said first output signal, in response to a second input signal which is complimentary with said first input signal,
a plurality of high breakdown voltage inverters connected between said first power supply and said second power supply, and configured to output a third output signal in response to a first control signal and said first output signal from said level shifter and output a fourth output signal which is complimentary with said third output signal, in response to a second control signal which is complimentary with said first control signal, and said second output signal from said level shifter; and
a plurality of P-type transistors connected between said first power supply and a power supply output node, and configured to respectively supply said first voltage to said power supply output node in response to said fourth output signals from said plurality of high breakdown voltage inverters;
a power recovery capacitance element connected between a first node and said second power supply;
an inductance element connected between a second node and said power supply output node;
a first diode having an anode and a cathode connected with said second node;
a second diode having a cathode and an anode connected with said second node;
a first switch connected between said power supply output node and said second power supply;
a second switch connected between said first node and said anode of said first diode;
a third switch connected between said first power supply and said power supply output node, as said plurality of high breakdown voltage P-type transistors in said level shift output circuit;
a fourth switch connected between said first node and said cathode of said second diode; and
an input signal processing circuit connected with said first to fourth switches and configured to turn on said first to fourth switches in this order,
wherein a voltage supplied to said power supply output node is used as a power supply voltage of a high breakdown voltage buffer, and a capacitance element is connected with an output of said high breakdown voltage buffer through a data electrode,
wherein when said first switch is turned on, electric charges accumulated in said capacitance element is discharged,
wherein when said second switch are turned on, the electric charges accumulated in said power recovery capacitance element are supplied to said capacitance element through said second switch, said first diode, said inductance element, said power supply output node, and said high breakdown voltage buffer,
wherein when said third switch is turned on, said first voltage is supplied to said power supply output node, and
wherein when said fourth switch is turned on, the electric charges accumulated in said capacitance element is accumulated by said power recovery capacitance element through said high breakdown voltage buffer, said power supply output node, said inductance element, said second diode, said fourth switch.

9. The electric power recovery circuit according to claim 8, wherein said input signal processing circuit executes a process in a first mode to output said first input signal to said level shifter in said level shift output circuit and to output said first control signal to said plurality of high breakdown voltage inverters in said level shift output circuit, when said third switch is turned off, and executes a process in a second mode to output said second input signal to said level shifter and to output said second control signal to said plurality of high breakdown voltage inverters, when said third switch is turned on.

10. The power recovery circuit according to claim 9, wherein said first, second, and fourth switches are turned on in response to an ON control signal and turned off in response to an OFF control signal, and
wherein said input signal processing circuit:
executes a process in said first mode to output said ON control signal to said first switch, to output said OFF control signal to said second and fourth switches, and to turn off said third switch, in a first period,
executes a process in said first mode to output said ON control signal to said second switch and to output said OFF control signal to said first and fourth switches in a second period after said first period,
executes a process in said second mode to output said FF control signal to said first, second and fourth switches, and to turn on said third switch, in a third period after said second period, and
executes a process in said first mode to output said ON control signal to said fourth switch, and to output said OFF control signal to said first and second switches, in a fourth period after said third period.

11. The power recovery circuit according to claim 8, wherein said first, second, and fourth switches are N-type transistors.

12. The power recovery circuit according to claim 8, wherein when testing each of said plurality of high breakdown voltage P-type transistors as said third switch, said input signal processing circuit executes a process in a test mode after said first mode, and
wherein said input signal processing circuit executes the process in said test mode to output said second input signal to said level shifter in said level shift output circuit, to output said second control signal to said plurality of high breakdown voltage inverters in said level shift output circuit in this order from a first inverter to a last inverter in said plurality of high breakdown voltage inverters, and to output said first control signal to said plurality of high breakdown voltage inverters other than one of said plurality of high breakdown voltage inverters to which said second control signal is supplied.

13. A plasma display apparatus comprising:
a plurality of pairs of discharge electrodes of a plurality of sustain electrodes and a plurality of scan electrodes;
a plurality of data electrodes provided to oppose to said plurality of pairs of discharge electrodes, and to form a plurality of display cells as a plurality of capacitance elements at intersections of said plurality of pairs of discharge electrodes and said plurality of data electrode;
a scan driver configured to drive said plurality of scan electrodes;
a sustain driver configured to drive said plurality of sustain electrodes;
a data driver configured to drive said plurality of data electrodes;
a power recovery circuit which comprises:
a level shift output circuit which comprises:
a level shifter connected between a first power supply which supplies a first voltage and a second power supply which supplies a second voltage which is lower than the first voltage, and configured to output a first output signal in response to a first input signal, and output a second output signal which is complimentary with said first output signal, in response to a second input signal which is complimentary with said first input signal,
a plurality of high breakdown voltage inverters connected between said first power supply and said second power supply, and configured to output a third output signal in response to a first control signal and said first output signal from said level shifter and output a fourth output signal which is complimentary with said third output signal, in response to a second control signal which is complimentary with said first control signal, and said second output signal from said level shifter, and
a plurality of P-type transistors connected between said first power supply and a power supply output node, and configured to respectively supply said first voltage to said power supply output node in response to said fourth output signals from said plurality of high breakdown voltage inverters;
a power recovery capacitance element connected between a first node and said second power supply;
an inductance element connected between a second node and said power supply output node;
a first diode having an anode and a cathode connected with said second node;
a second diode having a cathode and an anode connected with said second node;
a first switch connected between said power supply output node and said second power supply;
a second switch connected between said first node and said anode of said first diode;
a third switch connected between said first power supply and said power supply output node, as said plurality of high breakdown voltage P-type transistors in said level shift output circuit;
a fourth switch connected between said first node and said cathode of said second diode; and
an input signal processing circuit connected with said first to fourth switches and configured to turn on said first to fourth switches in this order,
wherein a voltage supplied to said power supply output node is used as a power supply voltage of a high breakdown voltage buffer, and a capacitance element is connected with an output of said high breakdown voltage buffer through a data electrode,
wherein when said first switch is turned on, electric charges accumulated in said capacitance element is discharged,
wherein when said second switch are turned on, the electric charges accumulated in said power recovery capacitance element are supplied to said capacitance element through said second switch, said first diode, said inductance element, said power supply output node, and said high breakdown voltage buffer,
wherein when said third switch is turned on, said first voltage is supplied to said power supply output node, and
wherein when said fourth switch is turned on, the electric charges accumulated in said capacitance element is accumulated by said power recovery capacitance element through said high breakdown voltage buffer, said power supply output node, said inductance element, said second diode, said fourth switch,
wherein said data driver comprises:
an output control circuit configured to convert a video image into data pulse voltages in an address period;
a plurality of level shift circuits provided respectively for said plurality of data electrodes to convert voltage levels of said data pulse voltage into write levels in said plurality of display cells; and
a plurality of high breakdown voltage buffers provided respectively for said plurality of data electrodes to output said data pulse voltages from said plurality of level shift circuits to said plurality of data electrodes, and
wherein an output of said power recovery circuit is used for power for said plurality of level shift circuits and said plurality of high breakdown voltage buffers.

14. The plasma display apparatus according to claim 13, further comprising a control section,
wherein said control section:
controls in a reset period, said sustain driver and said scan driver to supply voltages to said plurality of sustain electrodes and said plurality of scan electrodes so as to adjust electric charges accumulated between said plurality of sustain electrodes and said plurality of scan electrodes when sustain discharge is performed,
controls in an address period after said reset period, said sustain driver, said scan driver, and said data driver to supply voltages to said plurality of sustain electrodes and said plurality of scan electrodes so as to perform write discharge between said plurality of data electrodes and said plurality of scan electrodes to write an image data in said display cells, and
controls in the sustain period after said address period, said sustain driver and said scan driver to supply voltages to said plurality of sustain electrodes and said plurality of scan electrodes so as to perform the sustain discharge between said plurality of sustain electrodes and said plurality of scan electrodes to emit light from said display cells to which the write discharge is performed.

15. The plasma display apparatus according to claim 13, wherein said control section:
controls said sustain driver to supply first setting voltage to said plurality of sustain electrodes, in said address period,
controls said scan driver to supply a scan pulse voltage which falls from a second setting voltage to a second voltage, to said plurality of scan electrodes in an order from a first one to a last one in said plurality of scan electrodes, after supplying the second setting voltage which is higher than said second voltage, and
controls said data driver to supply said data pulse voltage in response to said video data to said plurality of data electrodes.
